(19) United States
(12) Patent Application Publication
(10) Pub. No.: US 2007/0284138 A1
(43) Pub. Date: Dec. 13, 2007

(54) Circuit board

(75) Inventors: Chien-Liang Chen, Shueilin Township (TW); Chun-Yu Lee, Sinying City (TW); Shih-Ping Chou, Taoyuan City (TW)

Correspondence Address: RABIN & Berdo, PC, 1101 14TH STREET, NW, SUITE 500, WASHINGTON, DC, 20005, US

(73) Assignee: AU OPTRONICS CORP., Hsinchu (TW)

(21) Appl. No.: 11/591,576

(22) Filed: Nov. 2, 2006

(30) Foreign Application Priority Data
Jun. 12, 2006 (TW) 95120833

(51) Int. Cl. H05K 1/16

(52) U.S. Cl. 174/260

(57) ABSTRACT

A circuit board is provided. The circuit board includes a first metal layer, at least a second metal layer and at least an insulating layer. The first metal layer has at least a solder pad. The second metal layer does not overlap with the solder pad. The insulating layer is disposed between the second metal layer and the first metal layer.

This application claims the benefit of Taiwan patent application Serial No. 095120833, filed JUN. 12, 2006, the subject matter of which is incorporated herein by reference.

### BACKGROUND OF THE INVENTION

1. Field of the Invention

The invention relates in general to a circuit board, and more particularly to a circuit board whose second metal layer does not overlap with the solder pad.

2. Description of the Related Art

The circuit board is categorized as single-layered circuit board, double-layered circuit board and multi-layered circuit board according to the number of circuit layers. The multi-layered circuit board has multiple layers of circuit layers and is electrically connected to the circuit layers via a through hole or a blind hole. As the electronic products are headed towards the current trend of lightweight, slimness, and compactness, the multi-layered circuit board being capable of stacking and contracting the circuit layers on a small-sized circuit board is gained an increasing range of application.

Referring to FIG. 1, a diagram of a conventional circuit board 100 is shown. The circuit board 100 is a conventional double-layered circuit board. The circuit board 100 includes a first metal layer 110, a second metal layer 120 and an insulating layer 130. The first metal layer 110 is disposed close to a surface of the circuit board 100. The circuit board 100 further includes a protection layer 140 covering the first metal layer 110 and having at least an opening 140a for exposing a part of the first metal layer 110 to form a solder pad 110a. The second metal layer 120 is disposed close to the other surface of the circuit board 100. The insulating layer 130 is disposed between the second metal layer 120 and the first metal layer 110 for electrically isolating the second metal layer 120 and the first metal layer 110.

As shown in FIG. 1, An anisotropic conductive film (ACF) 910 on the solder pad 110a is solidified to form a soldering contact point. Wherein the ACF 910 is solidified by a heating machine. The flexible circuit board 900 is electrically connected to the internal circuit of the circuit board 100 via the soldering contact point, and is even electrically connected to another flexible circuit board or package structure via the internal circuit of the circuit board 100.

Referring to FIG. 2, a top view of the circuit board 100 of FIG. 1 is shown. The circuit board 100 has a number of solder pads 110a. Wherein the second metal layer 120 partly overlaps with the solder pads 110a, as shown in FIG. 1 and FIG. 2.

Referring to FIG. 3, a diagram of another conventional circuit board 200 is shown. The circuit board 200 is a quadric-layered circuit board. The circuit board 200 includes a first metal layer 210, three layers of second metal layer 220 and three layers of insulating layer 230. The first metal layer 210 is disposed close to a surface of the circuit board 200. There is a protection layer 240 covering the first metal layer 210 and having at least an opening 240a for exposing a part of the first metal layer 210 to form a solder pad 210a. The second metal layer 220 is disposed at the position inner the circuit board 200 or close to the other surface of the circuit board 200. The insulating layer 230 is disposed between the second metal layers 220 and the first metal layers 210 for electrically isolating the second metal layers 220 and the first metal layers 210.

As shown in FIG. 3, An ACF 910 on the solder pad 210a is solidified to form a soldering contact point on the flexible circuit board 900.

Referring to FIG. 4, a temperature curve of the circuit board 100 and the circuit board 200 is shown. Under the same heating parameters such as the temperature of the thermal source, the heating rate or the distance from the thermal source, a heating machine respectively heats the circuit board 100 and the circuit board 200 and the temperature curve of the solder pad 110a and the temperature curve of the solder pad 210a are respectively measured. The temperature of the solder pad 110a is increased from 160° C. to 200° C., while the temperature of the solder pad 210a is increased from 140° C. to 160° C. The circuit board 200 is a quadric-layered circuit board, while the circuit board 100 is a double-layered circuit board, so the circuit board 200 has more circuit layers than the circuit board 100. Wherein the circuit layer is made from a conductive metal. During the heating process of the circuit board 200, the solder pad 210a is radiated via more circuit layers, so the temperature of the solder pad 210a cannot be effectively increased.

As shown in FIG. 3, during the process of soldering the flexible circuit board 900 with the circuit board 100 or the circuit board 200, a solidifying temperature must be applied to the ACF 910 to form a solidified soldering contact point. If the temperature of the solder pad 210a is not high enough, crack, hole or detachment might occur to the soldering contact point.

However, in the conventional circuit boards, the circuit boards have different number of layers thereof. Therefore the temperature of the solder pad varies widely. Consequently, crack, hole or detachment occurs to the soldering contact point often, resulting in the following problems:

Firstly, the structural strength of the soldering contact point is weakened. Once crack, hole or detachment occurs to the soldering contact point, the structural strength of the soldering contact point is largely weakened. To the worst, the package structure or the flexible circuit board will lose electrical functions.

Secondly, the operation of the heating machine becomes difficult. During the soldering process of the circuit board, the temperature of the solder pad can be increased by adjusting the parameters of manufacturing process such as increasing the temperature of the thermal source, increasing the temperature of heating rate or reducing the distance from the thermal source. However, during the process of adjusting the heating machine, the required parameters of the manufacturing process can not be precisely obtained. Moreover, during the process of replacing the circuit board, the machine will be idled when adjusting the parameters of manufacturing process.

Thirdly, the flexibility of manufacturing process is reduced. Different parameters of manufacturing process are required for manufacturing different circuit boards. Thus, different production lines are arranged for different parameters of manufacturing process. However, each production line can go with only one particular circuit board, thus the production line has very low flexibility and will be idled often.

Fourthly, more manufacturing hours are needed. After a conventional circuit board is soldered with a package structure or a flexible circuit board, a large number of labor are required for the reworking process of manual soldering to strengthen the structural strength of the soldering contact point. Manual soldering is time-consuming and often turns into a bottleneck in the production line and increases more manufacturing hours.

Fifthly, the manufacturing cost is increased. During the soldering process of a conventional circuit board, the manufacturing cost is increased due to the increase in the defect rate of the circuit board, the machine idle time, the production line idle time, and the reworking hours and labor.

### SUMMARY OF THE INVENTION

It is therefore an object of the invention to provide a circuit board whose second metal layer does not overlap with the solder pad, such that the heat of the solder pad does not radiate easily. The circuit board has the advantages that the structural strength is enhanced, the heating machine is easy to operate, the manufacturing flexibility is increased, and the manufacturing hours as well as the manufacturing cost are reduced.

The invention achieves the above-identified object by providing a circuit board. The circuit board includes a first metal layer, at least a second metal layer and at least an insulating layer. The first metal layer has at least a solder pad. The second metal layer does not overlap with the solder pad. The insulating layer is disposed between the second metal layer and the first metal layer.

The invention further achieves the above-identified object by providing a circuit board. The circuit board includes a first metal layer, at least a second metal layer and at least an insulating layer. The first metal layer has at least a solder pad. The second metal layer has at least a gap corresponding to the solder pad. The insulating layer is disposed between the second metal layer and the first metal layer.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a diagram of a conventional circuit board 100;

FIG. 2 is a top view of the circuit board 100 of FIG. 1;

FIG. 3 is a diagram of another conventional circuit board 200;

FIG. 4 is a temperature curve of the circuit board 100 and the circuit board 200;

FIG. 5 is a diagram of a circuit board 300 according to a first embodiment of the invention;

FIG. 6 is a top view of the circuit board 300 of FIG. 5;

FIG. 7 is a temperature curve of the circuit board 100, the circuit board 200 and the circuit board 300;

FIG. 8 is a diagram of a circuit board 400 according to a second embodiment of the invention;

FIG. 9 is a top view of the circuit board 400 of FIG. 8;

FIG. 10 is a temperature curve of the circuit board 100, the circuit board 200 and the circuit board 400;

FIG. 11 is a top view of a circuit board 500 according to a third embodiment of the invention; and

FIG. 12 is a top view of a circuit board 600 according to a fourth embodiment of the invention.

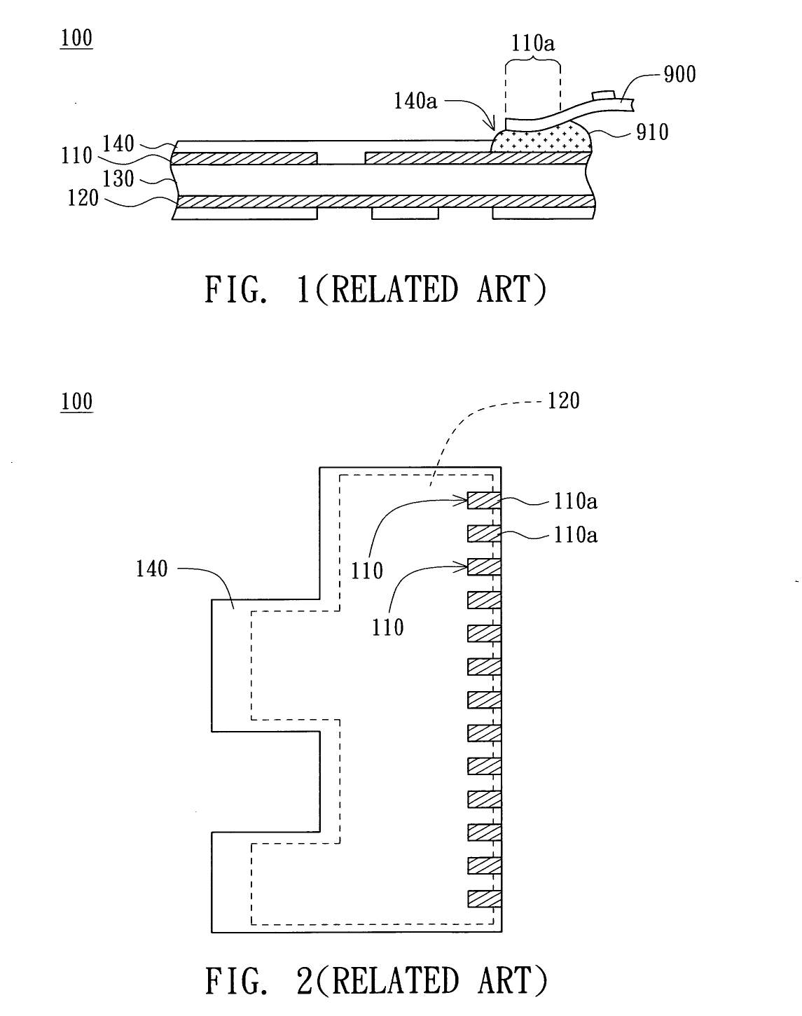

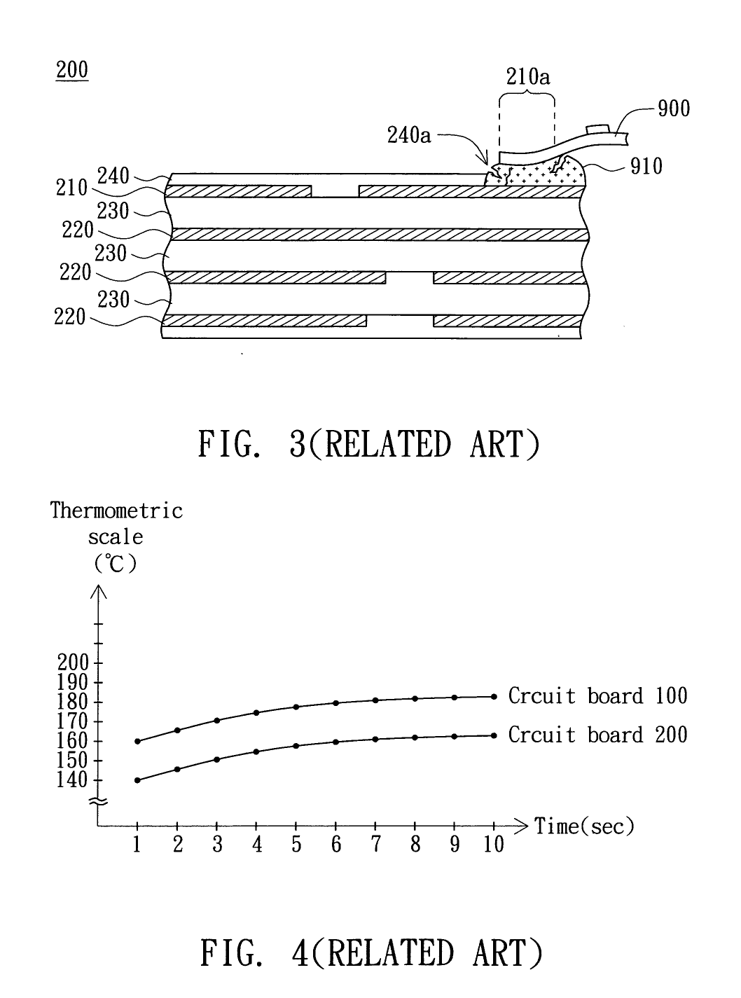

### DETAILED DESCRIPTION OF THE INVENTION

### First Embodiment

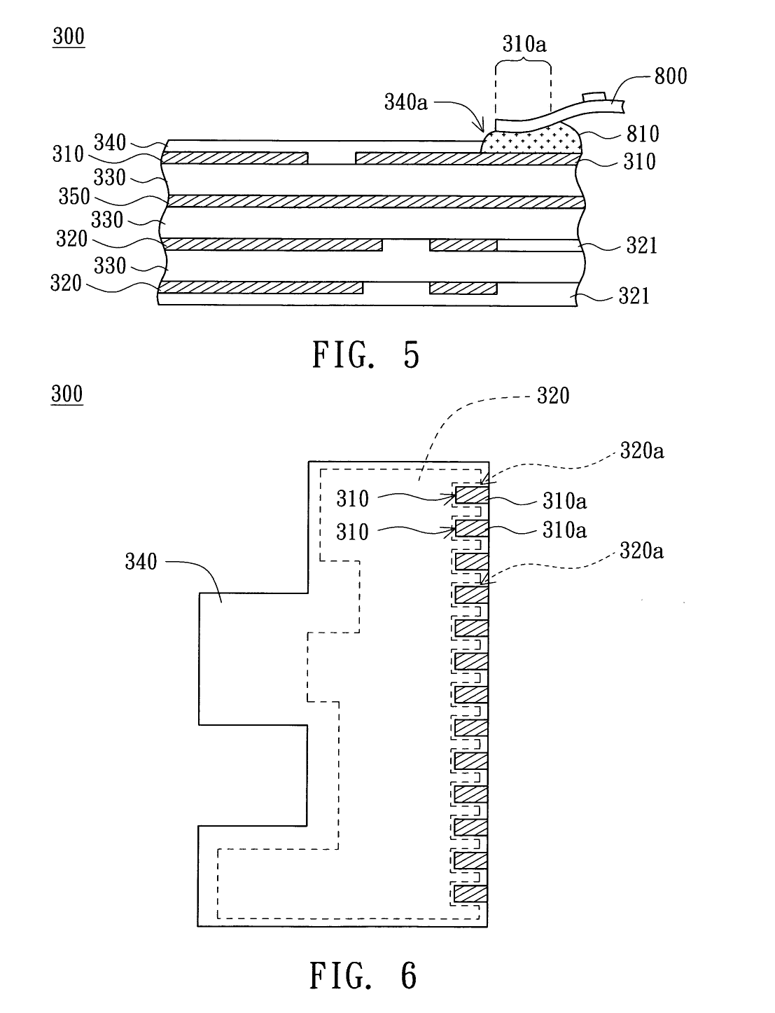

Referring to FIG. 5, a diagram of a circuit board 300 according to a first embodiment of the invention is shown. The circuit board 300 includes a first metal layer 310, at least a second metal layer 320 and at least an insulating layer 330. The first metal layer 310 has at least a solder pad 310a. The insulating layer 330 is disposed between the second metal layer 320 and the first metal layer 310. Referring to FIG. 6, a top view of the circuit board 300 of FIG. 5 is shown. The second metal layer 320 has at least a gap 320a corresponding to the solder pad 310a.

As shown in FIG. 5, in the present embodiment of the invention, the circuit board 300 is a quadric-layered printed circuit board. The circuit board 300 includes a layer of the first metal layer 310, two layers of the second metal layer 320, a layer of the third metal layer 350 and three layers of the insulating layer 330. The insulating layer 330 is disposed between any two layers of the first metal layer 310, the second metal layer 320 and the third metal layer 350 for electrically isolating the first metal layer 310, the second metal layers 320 and the third metal layers 350.

The first metal layer 310 is disposed close to a surface of the circuit board 300. There is a protection layer 340 covering the first metal layer 310 and having at least an opening 340a for exposing a part of the first metal layer 310 to form the solder pad 310a. The solder pad 310a is used for soldering with a flexible circuit board or a package structure. In the present embodiment of the invention, the solder pad 310a is electrically connected with a flexible circuit board 800 via an anisotropic conductive film (ACF) 810. The ACF 810 disposed on the solder pad 310a is solidified to form a soldering contact point by a heating machine. The flexible circuit board 800 is electrically connected to the circuit board 300 via the soldering contact point.

Referring to FIG. 6, a top view of the circuit board 300 of FIG. 5 is shown. The circuit board 300 has a number of solder pads 310a. In the present embodiment of the invention, the solder pad 310a is disposed on the edge of the first metal layer 310. The second metal layer 320 has a number of gaps 320a corresponding to the solder pads 310a. Preferably, the gap 320a is larger than the solder pad 310a.

As shown in FIG. 5, the gap 320a of the second metal layer 320 is filled with an insulating material 321. There are three layers of insulating layer 330, two layers of insulating material 321 and a layer of third metal layer 350 disposed under the solder pads 310a. The first metal layer 310, the second metal layer 320 and the third metal layer 350 are made from a high thermal conductive material, while the insulating layer 330 and insulating material 321 are made from a low thermal conductive material. During the heating process of the circuit board 300, the more low thermal conductive material corresponding to the solder pad 310a there are, the less the radiation of heat will be.

Particularly, in the present embodiment of the invention, one of the second metal layers 320 is a ground circuit layer. Generally speaking, the ground circuit layer has a large area, and the heat of the solder pad 310a is easily radiated via vertically conducting to the large-sized second metal layer 320. The insulating material filled in the part of the second metal layer 320 corresponding to the solder pad 310a can avoid the temperature of the solder pad 310a being radiated via the second metal layer 320.

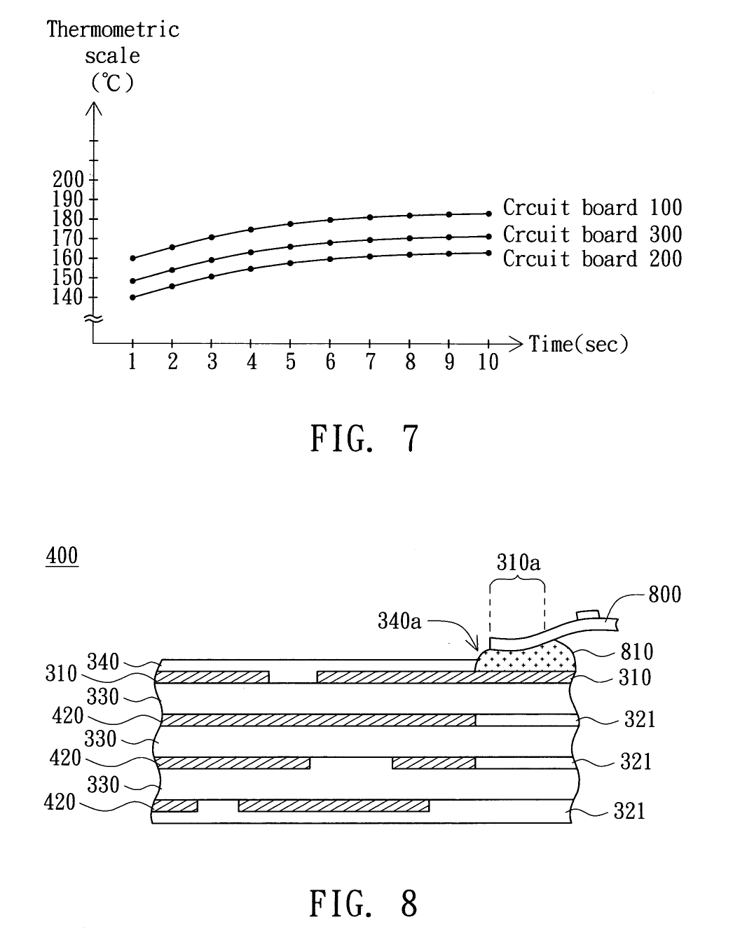

Referring to FIG. 7, a temperature curve of the circuit board 100, the circuit board 200 and the circuit board 300 is shown. Both the circuit board 300 and the circuit board 200 are a quadric-layered circuit board, while the circuit board 100 is a double-layered board. The gap 320a of the second metal layer 320 in the circuit board 300 corresponds to the solder pad 310a. To the contrary, the second metal layer 220 in the circuit board 200 partially overlaps with the solder pad 210a. Moreover, there are more low thermal conductive material corresponding to the underneath of the solder pad 310a than corresponding to the solder pad 210a. Therefore the heat of the solder pad 310a will not be quickly transmitted to the second metal layer 320 disposed underneath via vertical conduction and the temperature of the solder pad 310a will not go down quickly via the large-sized second metal layer 320. Hence, during the heating process of the circuit board 300 and the circuit board 200, the temperature of the solder pad 310a is higher than the temperature of the solder pad 210a. On the other hand, during the heating process of the circuit board 300 and the circuit board 200, the temperature of the solder pad 310a is closer to the temperature of the solder pad 110a of the circuit board 100 than the temperature of the solder pad 210a is.

Thereby, despite the circuit board 300 has more circuit layers than the circuit board 100, the solder pad 310a of the circuit board 300 is still able to produce a temperature curve close to that produced by the solder pad 100a of the circuit board 100.

### Second Embodiment

The circuit board 400 of the present embodiment of the invention differs with the circuit board 300 of the third embodiment in the number of layers of the second metal layer 420 and the disposition of the second metal layer 420, and the similarities are not repeated here. Referring to FIG. 8, a diagram of a circuit board 400 according to a second embodiment of the invention is shown. In the present embodiment of the invention, the circuit board 400 includes a layer of the first metal layer 310, three layers of the second metal layer 420 and three layers of the insulating layer 330. Wherein the three layers of the second metal layer 420 do not overlap with the solder pad 310a.

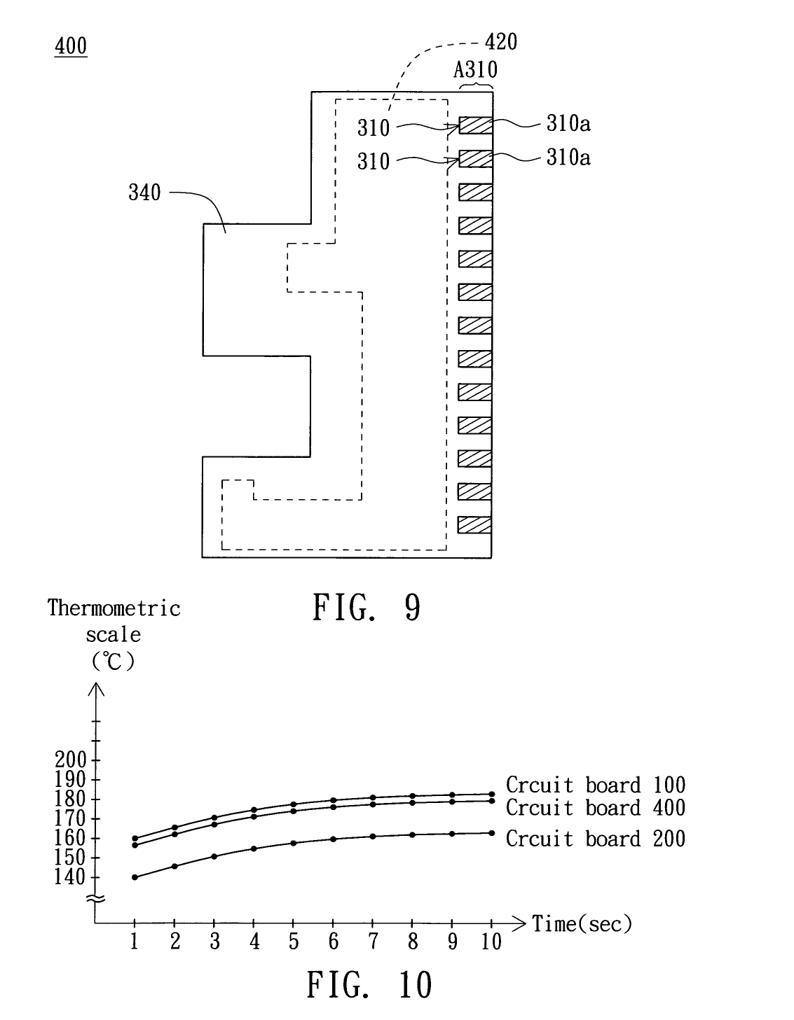

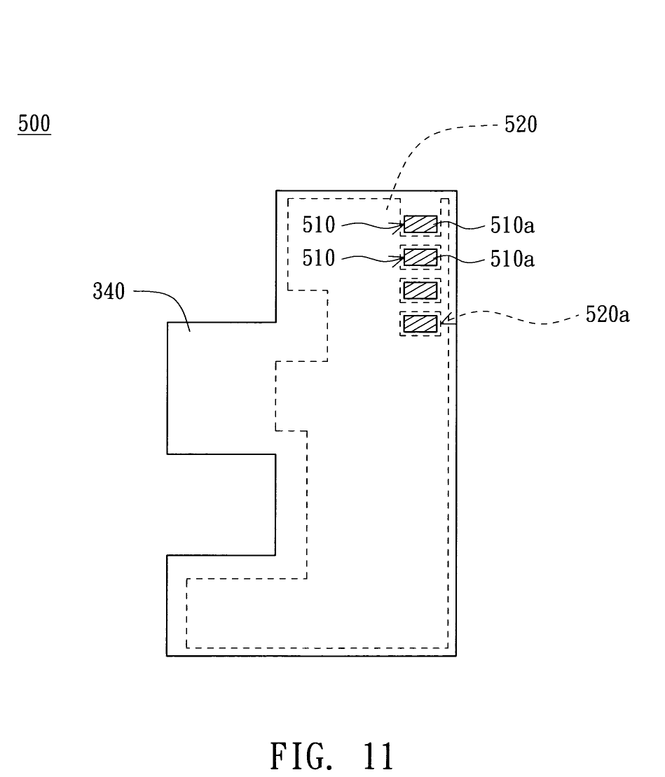

Referring to FIG. 9, a top view of the circuit board 400 of FIG. 8 is shown. The first metal layer 310 has a number of solder pads 310a arranged inside an area A310. In the present embodiment of the invention, the area A310 is disposed at an edge of the circuit board 400, and the second metal layer 420 does not overlap with the area A310.

Referring to FIG. 10, a temperature curve of the circuit board 100, the circuit board 200 and the circuit board 400 is shown. Compared with the circuit board 400 and the circuit board 300, there are more low thermal conductive material corresponding underneath the solder pad 410a than corresponding to the solder pad 310a, so it is not easy for the solder pad 410a to radiate the heat by vertical conduction. During the heating process of the circuit board 400 and the circuit board 300, the temperature of the solder pad 410a is higher than the temperature of the solder pad 310a. On the other hand, during the heating process of the circuit board 400 and the circuit board 300, the temperature of the solder pad 410a is closer to the temperature of the solder pad 110a of the circuit board 100 than the temperature of the solder pad 310a is.

Thereby, despite the circuit board 400 has more circuit layers than the circuit board 100 has, the solder pad 410a of the circuit board 400 is still able to produce a temperature curve close to that produced by the solder pad 110a of the circuit board 100.

### Third Embodiment

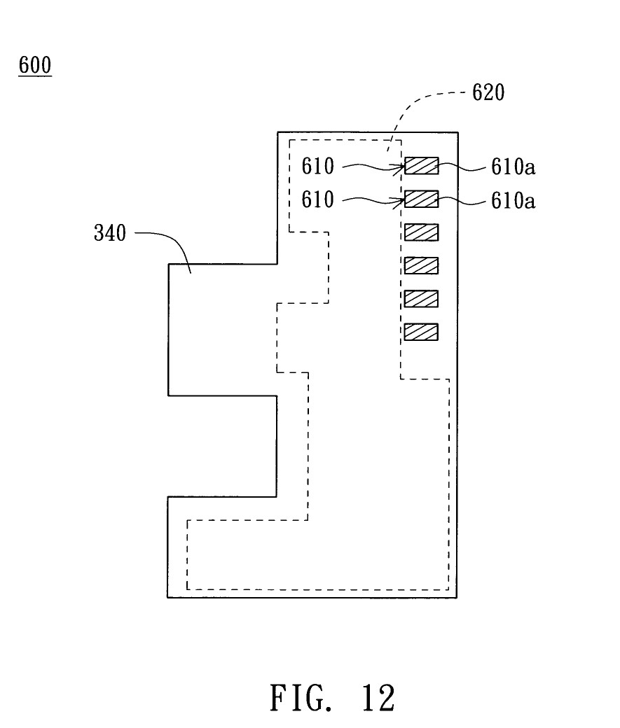

The circuit board 500 of the present embodiment of the invention differs with the circuit board 300 of the first embodiment in the disposition of the solder pad 510a and the second metal layer 520, and the other similarities are not repeated here. Referring to FIG. 11, a top view of a circuit board 500 according to a third embodiment of the invention is shown. In the circuit board 500, a number of solder pads 510a are disposed on the inner side of the first metal layer 510. The second metal layer 520 has a number of gaps 520a corresponding to the solder pad 510a, so it is not easy for the solder pad 610a to radiate the heat by vertical conduction.

In the present embodiment of the invention, despite the solder pad 510a is disposed on the inner side of the first metal layer 510, the second metal layer 520 can be disposed according to the disposition of the solder pad 510a to avoid the heat of the solder pad 510a being radiated easily by vertical conduction during the heating process. Thus, the circuit board 500 has an excellent soldering contact point.

### Fourth Embodiment

The circuit board 600 of the present embodiment of the invention differs with the circuit board of the second embodiment in the disposition of the solder pad 610a and the second metal layer 620, and the other similarities are not repeated here. Referring to FIG. 12, a top view of a circuit board 600 according to a fourth embodiment of the invention is shown. In the circuit board 600, a number of solder pads 610a are disposed on the inner side of the first metal layer 610. Moreover, the second metal layer 620 does not overlap with the solder pad 610a, so it is not easy for the heat of the solder pad 610a to be radiated by vertical conduction. Thus, the circuit board 600 has an excellent soldering contact point.

According to the four embodiments disclosed above, despite the circuit boards 300, 400, 500 and 600 of the invention are exemplified by a quadric-layered circuit board, the circuit board of the invention can have two layers or more than four layers. Any circuit boards having a second metal layer not overlapping with the solder pad for avoiding the heat of the solder pad being radiated easily via vertical conduction are within the scope of technology of the invention.

The circuit board disclosed in the above embodiment of the invention has a second metal layer not overlapping with the solder pad for avoiding the heat of the solder pad being radiated easily via vertical conduction and has the following advantages:

Firstly, the structural strength is enhanced. The heat of the solder pad is not easily radiated by vertical conduction, such that crack, hole or detachment will not occur to the soldering contact point. Thus, the structural strength of the soldering contact point is largely enhanced and the electrical characteristics of the package structure or the flexible circuit board are maintained.

Secondly, the heating machine is easy to operate. The second metal layer of the invention is applicable to various multi-layered circuit boards. Despite the parameters of manufacturing process are the same, the temperature curves of the solder pads are close for the circuit boards having different layers. Therefore, the trouble of machine adjustment is saved, and the idle time during the adjusting process of machine is avoided.

Thirdly, manufacturing flexibility is increased. The solder pads of the circuit boards of the invention can have close temperature curves. Therefore, when each production line adopts the same parameters of manufacturing process, the circuit boards of any batch can be assigned to any production line, largely increasing manufacturing flexibility.

Fourthly, manufacturing hours are decreased. As the soldering contact point has much less occurrences of crack, hole and detachment, the reworking process by manual soldering is decreased, largely reducing manufacturing hours.

Fifthly, manufacturing cost is reduced. During the soldering process of the circuit board of the invention, the circuit board has less defected products, machine idle time, production line idle time, reworking hours and reworking labor, further reducing manufacturing cost.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A circuit board, comprising:
a first metal layer having at least a solder pad;
at least a second metal layer not overlapping with the solder pad; and
at least an insulating layer disposed between the second metal layer and the first metal layer.

2. The circuit board according to claim 1, further comprises:
a protection layer covering the first metal layer, wherein the protection layer has an opening for exposing the solder pad.

3. The circuit board according to claim 1, is a multi-layered printed circuit board.

4. The circuit board according to claim 1, wherein the solder pad is disposed on the edge of the first metal layer.

5. The circuit board according to claim 1, wherein the solder pad is disposed on the inner side of the first metal layer.

6. The circuit board according to claim 1, wherein the solder pad is soldered with a flexible circuit board or a package structure.

7. The circuit board according to claim 6, wherein the solder pad is soldered with the flexible circuit board or the package structure via an anisotropic conductive film (ACF).

8. The circuit board according to claim 1, wherein the first metal layer has a plurality of solder pads, arranged inside an area, and the second metal layer does not overlap with the area.

9. The circuit board according to claim 1, wherein the second metal layer is used for grounding.

10. The circuit board according to claim 1, wherein the first metal layer and the second metal layer are made from a high thermal conductive material, and the insulating layer is made from a low thermal conductive material.

11. A circuit board, comprises:
a first metal layer having at least a solder pad;
at least a second metal layer having at least a gap corresponding to the solder pad; and
at least an insulating layer disposed between the second metal layer and the first metal layer.

12. The circuit board according to claim 11, further comprises:
a protection layer covering the first metal layer, wherein the protection layer has an opening for exposing the solder pad.

13. The circuit board according to claim 11, is a multi-layered printed circuit board.

14. The circuit board according to claim 11, wherein the solder pad is disposed on the edge of the first metal layer.

15. The circuit board according to claim 11, wherein the solder pad is disposed on the inner side of the first metal layer.

16. The circuit board according to claim 11, wherein the solder pad is soldered with a flexible circuit board or a package structure.

17. The circuit board according to claim 11, wherein the solder pad is soldered with the flexible circuit board or the package structure via an anisotropic conductive film (ACF).

18. The circuit board according to claim 11, wherein the second metal layer is used for grounding.

19. The circuit board according to claim 11, wherein the first metal layer and the second metal layer are made from a high thermal conductive material, and the insulating layer is made from a low thermal conductive material.

20. The circuit board according to claim 11, wherein the gap is larger than the solder pad.

21. The circuit board according to claim 11, wherein the gap is filled with an insulating material.
